(19) United States
(12) Patent Application Publication
(10) Pub. No.: US 2010/0046276 A1
(43) Pub. Date: Feb. 25, 2010

(54) Systems and Methods for Handling Negative Bias Temperature Instability Stress in Memory Bitcells

(75) Inventors: Nan Chen, San Diego, CA (US); Cheng Zhong, San Diego, CA (US); Ritu Chaba, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/194,342

(22) Filed: Aug. 19, 2008

(51) Int. Cl. G11C 11/00; G11C 5/14; G11C 7/00

(52) U.S. Cl. 365/154; 365/189.011; 365/226

(57) ABSTRACT

A system and method reduce stress caused by NBTI effects by determining if a trigger event has occurred and if so inverting all input data values to the memory and all output data values from the memory during a period of time defined by the determined trigger event. In one embodiment, the trigger event is an alternate memory power-up.

### TECHNICAL FIELD

This disclosure relates generally to electronic memories and more specifically to systems and methods for handling negative bias temperature instability (NBTI) stress is in memory bitcells.

### BACKGROUND

Bitcells operate by holding a voltage value over a period of time. It is this held value that translates into either a “1” or a “0” during a read operation of the memory. PMOS bitcells are subject to negative bias temperature instability (NBTI), which causes significant threshold voltage shifts and drive current reduction to occur over time when the bitcell bias voltage is negative. The amount of the threshold shift is dependant upon many factors, including temperature and operating conditions. This is not a problem when the memory is being used for relatively short term storage of any particular bit, because the memory bit is effectively being “reset” with each memory bit change.

However, for some applications, such as instruction memories, the memory bitcells, once set, are maintained for very long periods of time. The stress on memory bitcells used for such applications can cause such cells to read improperly. As memories become smaller, particularly in the sub-micron range, the effects of NBTI increase to a point where memory instability results.

### BRIEF SUMMARY

Embodiments of the present invention are directed to a system and method for reducing stress caused by NBTI effects by determining if a trigger event has occurred. If so, all input data values to the memory and all output data values from the memory are inverted during a period of time defined by the determined trigger event. In one embodiment, the trigger event is an alternate memory power-up.

In one embodiment, a memory system is designed having an inversion control circuit for selectively inverting data input and data output values to and from the memory array, and having a toggle control operative such that the data input values and data output values are both either inverted or not inverted during a same time period.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawings, in which:

FIG. 1 shows a typical prior art bitcell.

FIG. 2 shows one embodiment of circuitry to reduce NBTI stress in a memory bitcell, in accordance with the teachings of the invention.

FIGS. 3, 4 and 5 show embodiments of a method for handling negative bias temperature instability stress in memory bitcells, in accordance with the teaching of the inventive concepts discussed herein.

### DETAILED DESCRIPTION

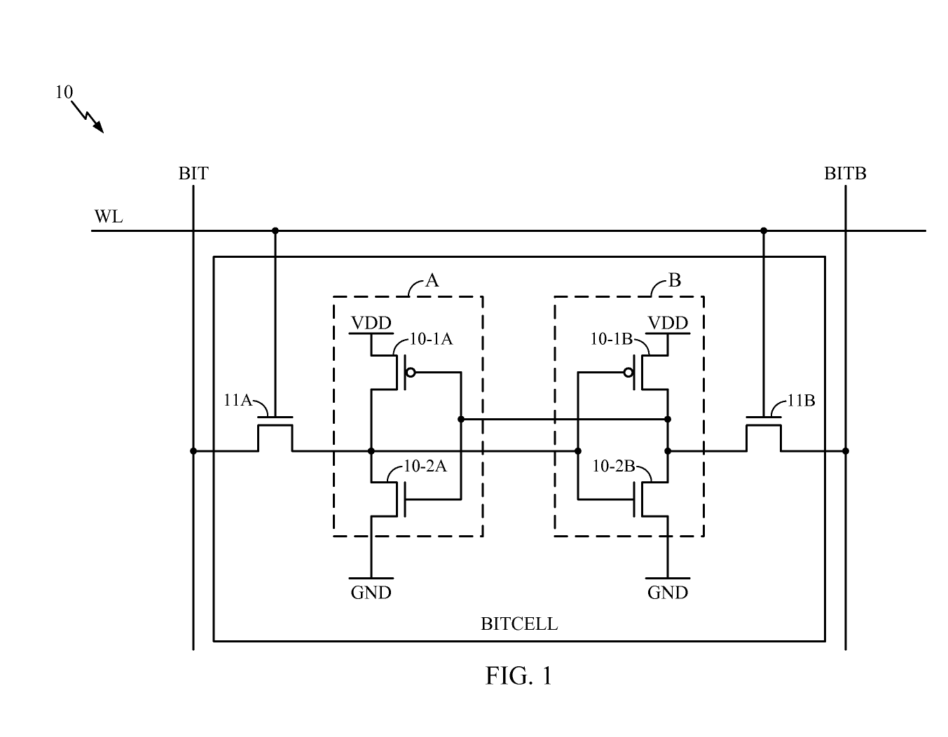

FIG. 1 shows a typical prior art six transistor static random access memory (SRAM) bitcell 10 in which devices 10-1A and 10-1B are pull-up devices, devices 10-2A and 10-2B are pull-down devices and devices 11A and 11B are pass gates. The bitcell 10 has two nodes, namely A and B with each section having a p-type metal oxide semiconductor (PMOS) and a n-type metal oxide semiconductor (NMOS) device, such as devices 10-1A and 10-2A. Assume that node A is storing a “1” while node B is storing a “0”. Also assume that the values stored in bitcell 10 are held for a long period of time. In such a situation, device 10-1B has a negative bias voltage between its gate and its source. Thus, device 10-1B is stressed due to the NBTI effect thereon. Because device 10-1A is storing a “1”, the bias voltage across its gate and source is negligible and thus device 10-1A is not under stress.

If this condition were allowed to continue for a long period of time, the NBTI stress would cause the threshold voltage of device 10-1B to shift and become unbalanced with respect to device 10-1A which is not under the same stress. This unbalance could cause the stored data to flip during a subsequent read-cell operation.

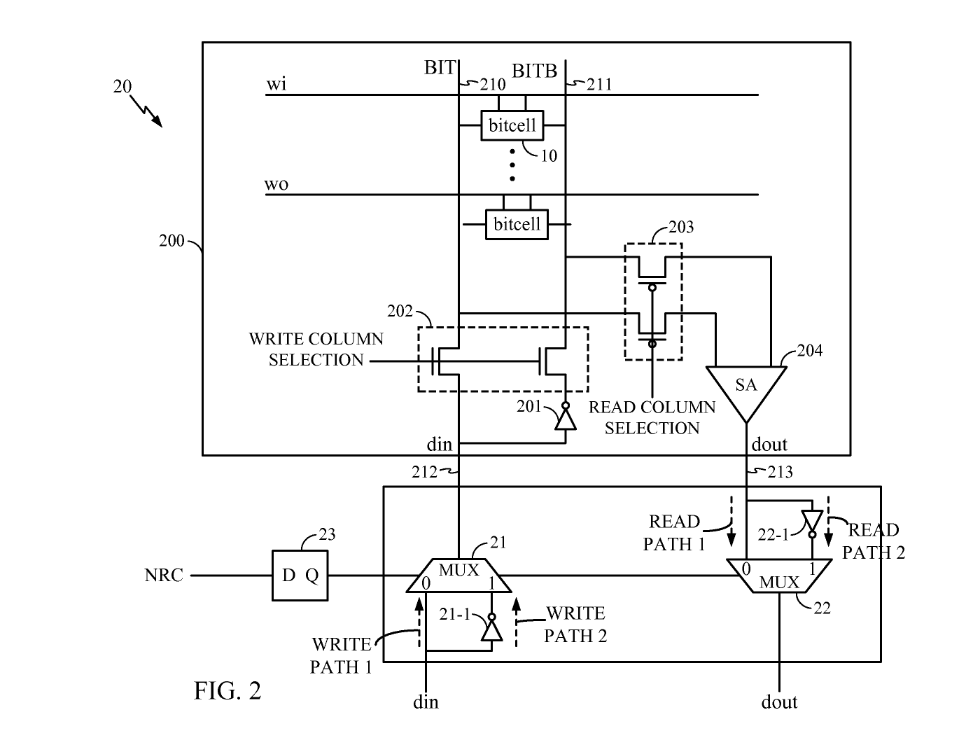

FIG. 2 shows an embodiment 20 of circuitry to reduce NBTI stress in a memory bitcell. Circuitry 200 is a portion of a typical SRAM memory having a plurality of bitcells 10 controlled by write switches 202 and read switches 203. Input into the memory for one bit line BIT 200 arrives directly from data in (din) lead 212 and is inverted by gate 201 for bit line BITB 211. Output from bit line BIT 210 and BITB 211 pass through sense amplifier 204 and out of the memory via data out (dout) lead 213. This structure is repeated for each pair of bit lines. This is a standard write/read circuit structure for a SRAM.

Stress on the memory bitcell is balanced by the addition of mux 21 for the input and mux 22 for the output. As will be discussed, at certain periods of time, such as when power is removed from the memory, all data in the memory will be read from the memory for storage in a non-volatile memory. At a subsequent point in time, such as when power is restored to the memory, the exact same data is written back into the memory, but during writing in the mux causes the bits to be reversed on all of the input bit lines. Thus, all bitcells that had a “1” on its A node (and a “0” on its B node) will now have a “0” on its A node and (a “1” on its B node). In this manner, the two nodes of each bitcell are effectively reversed each time power is applied and removed. Thus, the power-up cycle serves as a memory refresh thereby reducing the effects of NBTI on any particular node.

If nothing more were to happen, then all bits stored in memory would be reversed when read from the memory. However, when the readout occurs, the output of the A and B nodes are also then reversed so that the result is a proper readout.

In operation, mux 21 and mux 22 work in tandem so that when mux 21 reverses the input orientation of the input bits, mux 22 also reverses the output orientation of bits read from the memory during the same memory cycle. The muxes 21 and 22 are controlled by the NBTI select signal (NRC) via gate 23 which can be toggled by an external event such as a power reboot or by some other factor.

For example, if the NRC is set to 0 when the system is powered up, the input data will be written into the memory bitcell through write path 1 without any inversion and will be read out correctly through read path 1 during a read operation. The next time the system is powered up, the NRC will be automatically changed to “1” by software or a tracking circuit and the input data will be inverted and loaded into memories through write path 2 and inverter 21-1. The data will be read out through read path 2 and inverter 22-1 during read operation later. Memory users will not notice any difference from a data operation point of view. Because the data will be inverted and stored in the bitcell during different power up cycles, the PMOS devices in each bitcell will be applied with the same NBTI stress alternatively and will be balanced in terms of NBTI stress. In addition, the interface trap generated by the “on” state of bitcell PMOS devices during the last power up cycle will be partially annealed by the “off” state of PMOS devices during the next power up cycle. So, by balancing the bias stress and recovery effect, the NBTI effect will be reduced and the reliability of devices will be greatly improved.

One factor that must be considered when proposing changes to memory operation is that the memory speed of operation must not be compromised. In the system discussed above the only speed penalty is the delay associated with an additional gate of the mux, which is negligible. In addition, the circuit could be designed such that the gate of the mux acts as a memory output buffer (or part of the buffer) and thus no (or very little) speed is lost. The only structural penalty is the area consumed by the muxes on the device. The additional area required for the circuitry is also minimal.

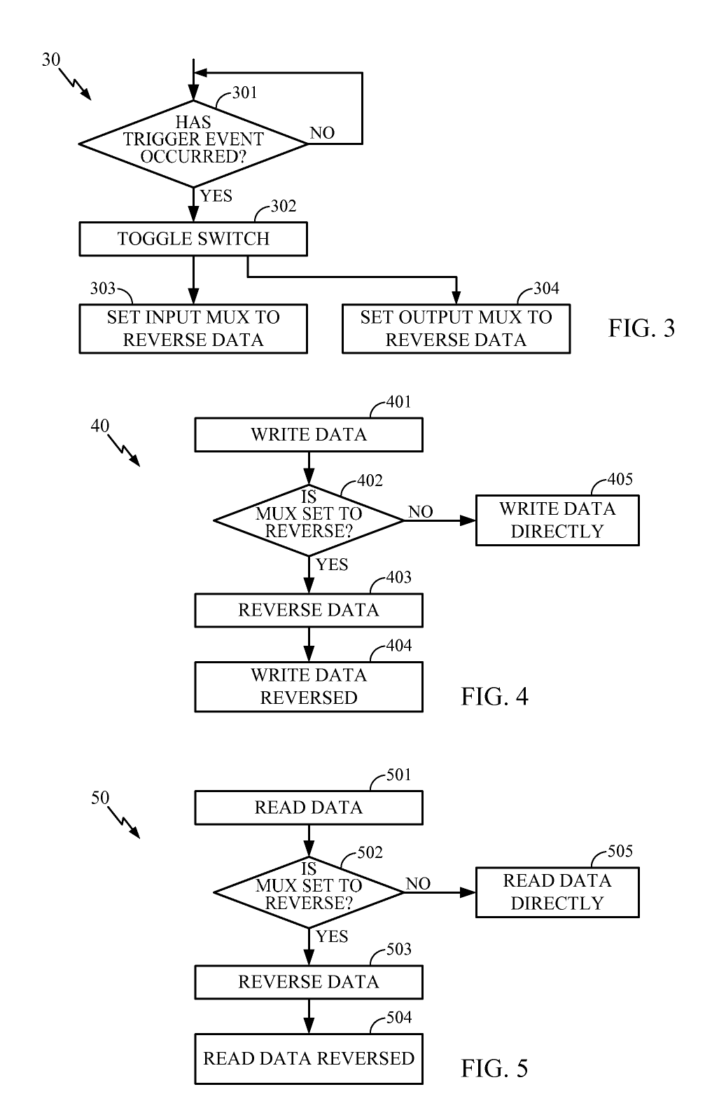

FIGS. 3, 4 and 5 show embodiments of methods for handling negative bias temperature instability stress in memory bitcells in accordance with the teachings of the inventive concepts discussed herein.

FIG. 3 shows method 30 in which process 301 determines if a trigger event has occurred. A trigger event could be a simple passage of time or any other externally caused event, random or otherwise. A preferable trigger event is the power-down/power-up cycle of the system in which the memory is employed. Using such a cycle as the trigger event means that on alternate power-ups of the memory, the trigger will become set and will remain set until the next memory power up when the trigger will unset.

If the trigger has occurred, then process 302 toggles a switch which then causes processes 303 and 304 to set the input and output muxes (or any other reversing control) to their opposite states from their current state.

FIG. 4 shows method 40 in which process 401 writes data into the bitcells of a memory. If process 402 determines that the mux (or other control) is not set to reverse, then the data is written into each bitcell via mux 21-1 of input 0 without modification at process 405. However, if process 402 determines that the mux (or other reversing control) is set to reverse, then processes 403 and 404 cause the data being written to be reversed by gate 21-1 and sent to the memory via input 1 of mux 21. The data is then stored in the respective bitcells in the opposite manner from what it would have been stored had the data not been reversed. For example, if a bitcell 10 would normally have a 0 in its A node and a 1 in its B node, that bitcell would now have a 1 in its A node and a 0 in its B node.

FIG. 5 shows method 50 in which process 501 reads data out of the bitcells of a memory. If process 502 determines that the mux (or other control) is not set to reverse, then the data is read out of the respective bitcells via mux 22 of input 0 without modification at process 505. However, if process 502 determines that the mux (or other reversing control) is set to reverse, then processes 503 and 504 cause the data being read out to be reversed by gate 22-1 and passed out of the memory via input 1 of mux 22. Thus, by reversing the data both on the input and on the output during a same memory cycle, the absolute value of the data is preserved while still allowing for “reverse” data storage at each bitcell. In this manner, the stress on the bitcell from NBTI is balanced over time, yielding a more stable SRAM memory.

Although the present invention and its advantages have been described in detail, it should be understood that various changes, substitutions and alterations can be made herein without departing from the spirit and scope of the invention as defined by the appended claims. For example, although the description has been with respect to 6T SRAM, other types of memory (e.g., dynamic RAM or 8T SRAM) would also benefit from the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for reducing negative bias temperature instability (NBTI) stress in a memory bitcell; said method comprising:
presenting for storage at said memory bitcell a data input value;
for a period of time, inverting said data input value before presenting said data input value to said bitcell for storage; and
during said period of time, inverting output data values from said bitcell.

2. The method of claim 1 wherein the method is operative in a memory system comprising a plurality of memory bitcells; the method further comprises:
inverting all data in and out of said memory system for at least one of said periods of time.

3. The method of claim 1 wherein said period of time is defined as a time between a power-up and a power-down cycle of a memory system.

4. A memory system comprising:
an inversion control circuit for selectively inverting data input values and data output values to and from a memory array; and
a toggle control operative such that both said data input values and said data output values are inverted or not inverted during a same time period.

5. The memory system of claim 4 wherein said memory array is a static random access memory (SRAM) array.

6. The memory system of claim 4 wherein said memory array comprises bitcells with each bitcell comprising at least one node having both PMOS and NMOS transistor devices.

7. The memory system of claim 4 wherein said time period is defined by a memory array power on and power off event.

8. The memory system of claim 4 wherein said inversion control comprises multiplexor circuitry having at least one pair of inputs for each of said input data value and output data value, and wherein one of said inputs of each said pair operates to invert data values passing through said input.

9. A circuit for use with static random access memory (SRAM) memory to reduce NBTI stress in memory bitcells, said circuit comprising:
a first multiplexor having an output connectable to a data input of said memory and having at least a pair of inputs for accepting data values for presentation to said data input through said first multiplexor;
a second multiplexor having at least a pair of inputs for accepting data values from said memory for presentation to a memory data output through said second multiplexor;
a first inverter for inverting data values presented to a particular one of said first multiplexor inputs;
a second inverter for inverting data values presented to a particular one of said second multiplexor inputs; and
an interconnection between said first and second multiplexor, said interconnection operable to facilitate said multiplexor working in tandem with each other such that when data has been input to said memory via said particular input of said first multiplexor, data is read from said memory via said particular input of said second multiplexor.

10. The circuit of claim 9 further comprising:
a toggle for enabling in tandem either said first or second inputs of said multiplexor for a period of time.

11. The circuit of claim 10 wherein said period of time is controlled, at least in part, by a power-up/power-down cycle of said memory.

12. A memory system comprising:
means for selectively inverting data input values and data output values to and from a memory array; and
means operative for coordinating said inversion such that said data input values and said data output values are both either inverted or not inverted during a same time period.

13. The memory system of claim 12 wherein said memory array is a six transistor (6T) SRAM array.

14. The memory system of claim 12 wherein said memory array comprises bitcells with each bitcell comprising at least one node having both PMOS and NMOS transistor devices.

15. The memory of system 14 wherein said time period is defined by a memory array power-on and power-off event.

16. A method for SRAM memory operation, said method comprising:
determining if a trigger event has occurred; and
inverting all input data values to said memory and all output data values from said memory during a period defined by the determined trigger event.

17. The method of claim 16 wherein said trigger event is an alternate memory power-up.
